(19) United States
(12) Patent Application Publication
(10) Pub. No.: US 2020/0404803 A1
(43) Pub. Date: Dec. 24, 2020

(54) CIRCUIT ASSEMBLY AND ELECTRICAL JUNCTION BOX

(71) Applicants: AutoNetworks Technologies, Ltd., Yokkaichi-shi, Mie (JP); Sumitomo Wiring Systems, Ltd., Yokkaichi-shi, Mie (JP); Sumitomo Electric Industries, Ltd., Osaka-shi, Osaka (JP)

(72) Inventor: Koki Uchida, Yokkaichi-shi, Mie (JP)

(21) Appl. No.: 16/772,345

(22) PCT Filed: Nov. 27, 2018
(86) PCT No.: PCT/JP2018/043503

§ 371 Date: Jun. 12, 2020

(30) Foreign Application Priority Data
Dec. 14, 2017 (JP) 2017-239352

(51) Int. Cl. H05K 7/20; H05K 1/18; H05K 1/02; H05K 7/14

(52) U.S. Cl. CPC H05K 7/2039; H05K 1/181; H02G 3/086; H05K 7/1427; H05K 2201/10409; H05K 1/0204

(57) ABSTRACT

A circuit assembly includes a substrate having a thermally conductive portion that passes through a substrate in the plate-thickness direction thereof, and that includes an electrically conductive path. A semiconductor package is mounted to the substrate and includes a chip. A resin portion covers the chip. A first lead portion is connected to the chip and is exposed on the substrate side of the resin portion. A second lead portion is connected to the chip and is exposed to the side opposite to the substrate side of the resin portion. A heat dissipating member is arranged facing the side opposite to the semiconductor package with respect to the substrate and is connected to the thermally conductive portion in such a way as to conduct heat. An electrically conductive member connects the second lead portion and the thermally conductive portion.

### CROSS-REFERENCE TO RELATED APPLICATIONS

This application is the U.S. national stage of PCT/JP2018/043503 filed on Nov. 27, 2018, which claims priority of Japanese Patent Application No. JP 2017-239352 filed on Dec. 14, 2017, the contents of which are incorporated herein.

### TECHNICAL FIELD

The present specification discloses a technique that relates to circuit assemblies and electrical junction boxes.

### BACKGROUND

A technique is conventionally known with which heat produced by electronic components that are mounted to substrates is dissipated from metal heat dissipating members. A semiconductor package that is arranged on a surface of a substrate in the electronic device of JP 2015-5643A (see FIG. 6) is formed as a single body including a chip, a lead frame that is connected by a layer of solder to both the upper and lower surfaces of the chip, and a molded resin that covers the chip. The portion of the upper surface of the lead frame that is connected to the upper surface of the chip is connected to the substrate by the layer of solder, and the portion of the upper surface of the lead frame that is connected to the lower surface of the chip is connected to a lead terminal. Also, the portion of the lead frame that is connected to the lower surface of the chip by the layer of solder includes a heat sink placed thereon, with a heat dissipating gel sandwiched between the lead frame and the heat sink. The heat of the semiconductor package mounted on the substrate is dissipated from the heat sink via the heat dissipating gel.

Meanwhile, a problem with the configuration described in JP 2015-5643A is that heat is dissipated via the heat sink provided on the opposite side of the semiconductor package to the substrate and therefore, compared to a configuration in which the heat sink is placed on the substrate-side of the semiconductor package for example, there is a space between the substrate and the heat sink due to the substrate and the heat sink being arranged separate from each other, which tends to cause the size of the device to increase.

The technique described in the present specification has been completed based on circumstances such as those described above, and an object thereof is to provide a circuit structure and an electrical junction box with which the heat of a semiconductor package can be dissipated from a heat dissipating member, while suppressing an increase in the size of the device.

### SUMMARY

A circuit assembly described in the present specification includes: a substrate that is provided with a thermally conductive portion that has thermal conductivity and passes through the substrate in the plate-thickness direction thereof, and that includes an electrically conductive path; a semiconductor package that is mounted to the substrate and includes a chip, a resin portion that covers the chip, a first lead portion that is connected to the chip and is exposed on the substrate side of the resin portion, and a second lead portion that is connected to the chip and is exposed to the side opposite to the substrate side of the resin portion; a heat dissipating member that is arranged facing the side opposite to the semiconductor package with respect to the substrate and is connected to the thermally conductive portion in such a way as to conduct heat; and an electrically conductive member that connects the second lead portion and the thermally conductive portion.

With this configuration, the heat of the chip in the semiconductor package can be dissipated from the heat dissipating member via the second lead portion, the electrically conductive member, and the thermally conductive portion. Thus, heat that has been transmitted from the chip to the second lead portion can be dissipated from the heat dissipating member without needing to provide the heat dissipating member on the second lead portion side, and therefore the heat of the semiconductor package can be dissipated from the heat dissipating member, while suppressing an increase in the size of the device.

The following are preferred embodiments of the technique disclosed in the present specification.

The semiconductor package further includes a plurality of third lead portions, the plurality of third lead portions include a control terminal and a power terminal that conducts a larger electrical current than the control terminal, and the electrically conductive member covers the power terminal and includes a cut-out portion that is cut out in such a way as to not cover the control terminal.

With such a configuration, thermal conductivity and heat dissipation are improved because the surface area of the plate surface of the electrically conductive member is increased due to the electrically conductive member covering the power terminal, and it is also possible to ensure insulation between the control terminal and the electrically conductive member due to the cut-out portion.

The circuit assembly further includes a plurality of the semiconductor packages, wherein the electrically conductive member connects the second lead portions and the thermally conductive portions of the plurality of semiconductor packages to each other in parallel.

With such a configuration, it is possible to dissipate the heat of a plurality of semiconductor packages because the electrically conductive members are connected in parallel, and it is therefore possible to reduce production costs in comparison to a configuration in which the electrically conductive members are provided individually on the semiconductor package.

The circuit assembly further includes a rivet that includes a shaft and a head portion that has a larger diameter than the shaft, wherein the substrate includes a thermally conductive hole that passes through the substrate in the plate-thickness direction thereof, and the shaft of the rivet is inserted into the thermally conductive hole to constitute the thermally conductive portion, and the head portion of the rivet is connected to the heat dissipating member in such a way as to conduct heat.

With such a configuration, it is possible to reduce production costs because ordinary inexpensive rivets can be used as the thermally conductive portions.

An electrical junction box that includes the circuit assembly, and a case that accommodates the circuit assembly.

### Advantageous Effects of Disclosure

With the technique described in the present specification, it is possible to suppress the enlargement of the device while dissipating the heat of the semiconductor package from the heat dissipating member.

### BRIEF DESCRIPTION OF DRAWINGS

FIG. 1 is a plan view showing a circuit assembly of a first embodiment.

FIG. 2 is an enlarged view of the vicinity of an electrically conductive member shown in FIG. 1.

FIG. 3 is a sectional view of an electrical junction box taken at position A-A in FIG. 1.

FIG. 4 is an enlarged view of the vicinity of the electrically conductive member in FIG. 3.

FIG. 5 is an exploded perspective view of the electrical junction box.

FIG. 6 is a sectional view of the electrical junction box of a second embodiment.

FIG. 7 is an enlarged sectional view of the vicinity of the electrically conductive member in FIG. 6.

FIG. 8 is an enlarged plan view of the vicinity of the electrically conductive member.

FIG. 9 is a plan view showing the circuit assembly of a third embodiment.

FIG. 10 is a plan view showing the conductive member.

### DETAILED DESCRIPTION OF PREFERRED EMBODIMENTS

### First Embodiment

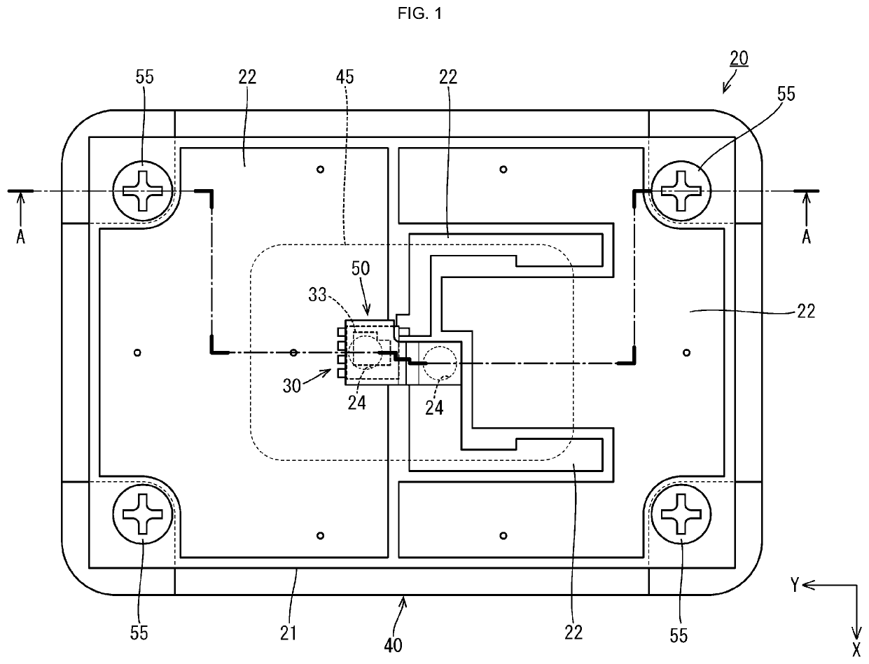

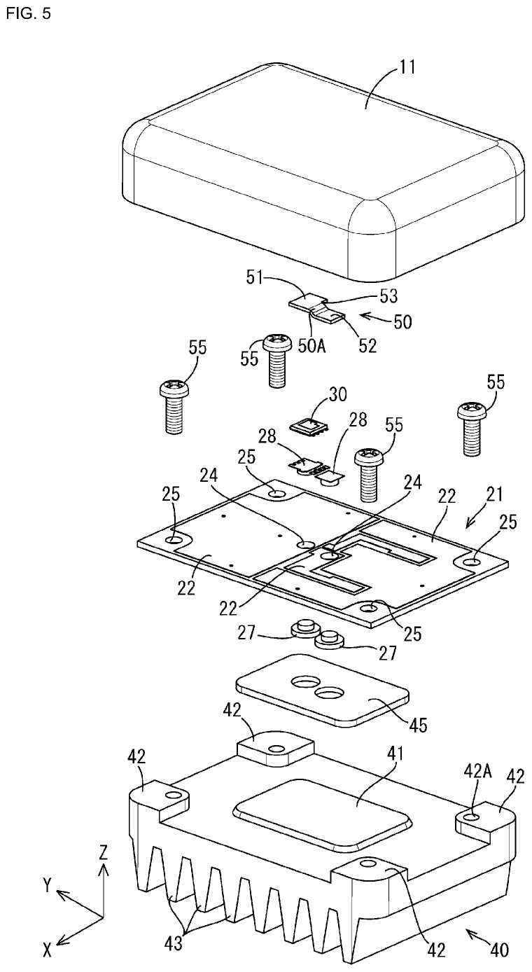

The following describes a first embodiment with reference to FIGS. 1 to 5.

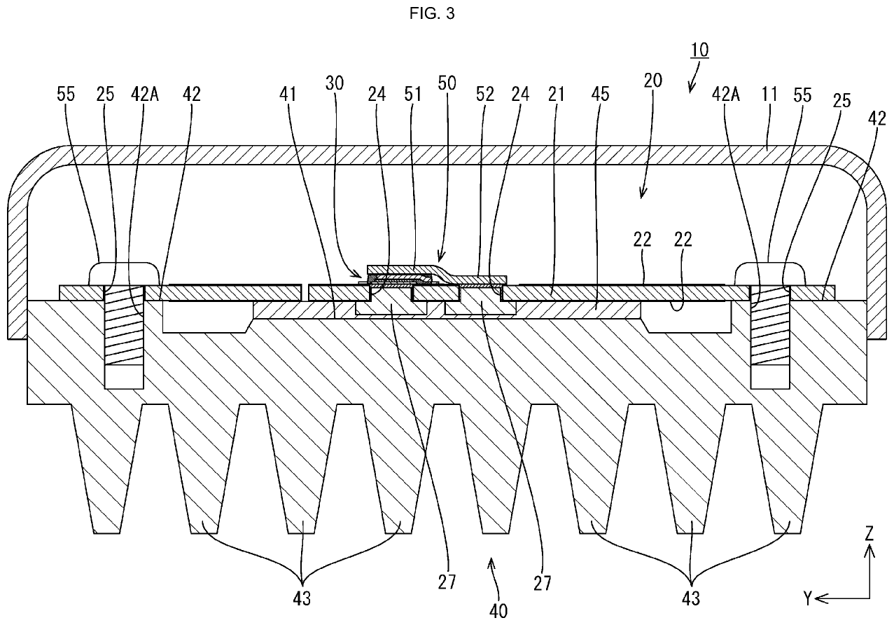

An electrical junction box 10 is arranged in a power supply path between a power source, such as a battery of a vehicle, and a load of an in-vehicle electrical component, such as lamp or a wiper, or a motor, and can be used for a DC-DC converter or an inverter for example. The electrical junction box 10 can be arranged in any direction, but in the following description, the X direction in FIG. 1 is forward, the Y direction in FIG. 3 is leftward, and the Z direction in FIG. 3 is upward.

### Electrical Junction Box 10

As shown in FIG. 3, the electrical junction box 10 includes a circuit assembly 20 and a case 11 that covers the circuit assembly 20. The case 11 is shaped like a box with the underside thereof opened, and is made from a metal such as aluminum or an aluminum alloy, or from a synthetic resin.

### Circuit Assembly 20

The circuit assembly 20 includes a substrate 21, a semiconductor package 30 that is mounted on the substrate 21, a heat dissipating member 40 that is arranged facing the lower side of the substrate 21 (the side of the substrate 21 that is opposite to the semiconductor package 30 side thereof) and dissipates heat that has been transmitted from the semiconductor package 30 and the like to the outside thereof, and a plate-shaped electrically conductive member 50 that connects the upper surface of the semiconductor package 30 and the upper surface of the substrate 21 to each other.

### Substrate 21

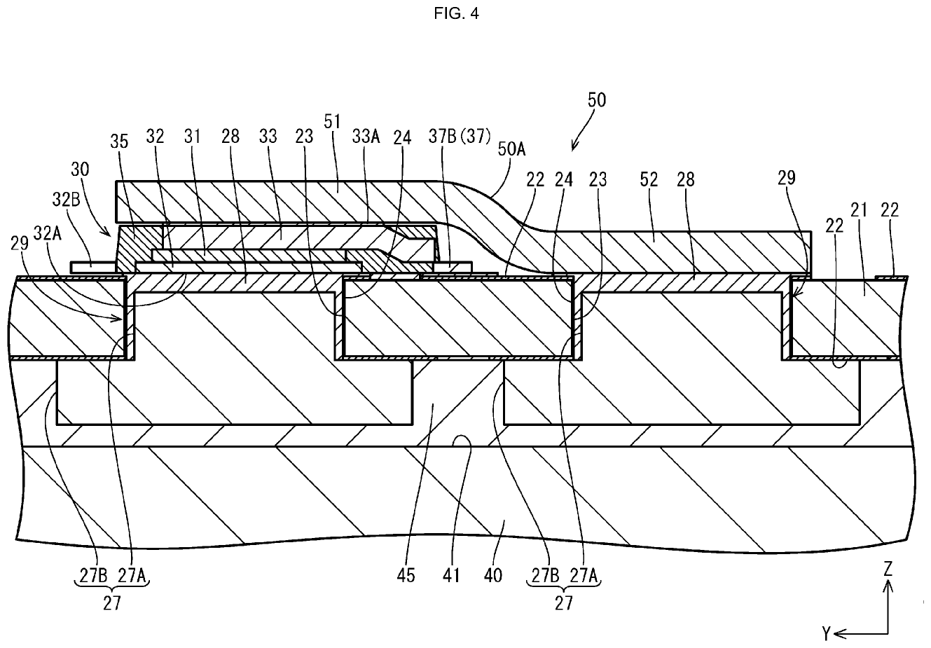

The substrate 21 is formed with printed wire technology in which electrically conductive paths 22 made from copper foil or the like are printed on both the upper surface and the lower surface of an insulating plate, which is made from an insulating material. The substrate 21 is formed with a pair of (a plurality of) circular thermally conductive holes 24 (through-holes), and four (a plurality of) circular screw-holes 25, all of which pass through the substrate 21 in the up-down direction (the thickness direction) thereof. The shafts of screws 55 are inserted into the screw-holes 25. As shown in FIG. 4, shafts 27A of a pair of rivets 27 are inserted to the left and right of the center of the substrate 21, and the entirety of the walls of the thermally conductive holes 24 are in areal contact with electrically conductive walls 23 that are made from a copper foil or the like. The electrically conductive walls 23 are continuous with the upper and lower electrically conductive paths 22 of the substrate 21, and the upper and lower electrically conductive paths 22 of the substrate 21 are electrically connected via the electrically conductive walls 23.

The rivets 27 are made from a metal such as copper, a copper alloy, aluminum, an aluminum alloy, iron, stainless steel, or the like, and include cylindrical shafts 27A, and cylindrical head portions 27B that are provided on one side of the shafts 27A in the axial direction thereof and have a larger diameter than the shafts 27A. The shafts 27A have a slightly smaller bore than the thermally conductive holes 24, and when the shafts 27A are inserted into the thermally conductive holes 24, solder 28 is arranged as a bonding material in gaps between the outer peripheral surface of the shafts 27A and the electrically conductive walls 23 (the walls of thermally conductive holes 24) and the gaps between the upper end surface of the shafts 27A and the electrically conductive member 50, and members in the vicinity thereof are bonded to each other by the solder 28. The electrically conductive walls 23, the rivets 27, and the solder 28 form a thermally conductive portion 29 that increases the thermal conductivity between the electrically conductive member 50 and the heat dissipating member 40.

### Semiconductor Package 30

The semiconductor package 30 is an electronic component that produces a large amount of heat through electrical conduction, and may be an FET (Field Effect Transistor) for example. The semiconductor package 30 includes a chip 31 as an integrated circuit, a first lead portion 32 that is connected to the lower surface of the chip 31 with the use of solder, a second lead portion 33 that is connected to the upper surface of the chip 31 with the use of solder, an adhesive, or the like, a resin portion 35 that completely covers the chip 31, and a plurality of third lead portions 37 that are electrically connected to the second lead portion 33 in the resin portion 35 and are aligned protruding outwardly from the side surface of the resin portion 35. Note that the third lead portions 37 and the like may protrude from the resin portion 35, but there is no limitation thereto, and a configuration is also possible in which the third lead portions 37 and the like are exposed from the resin portion 35 without protruding from the side surface of the resin portion 35.

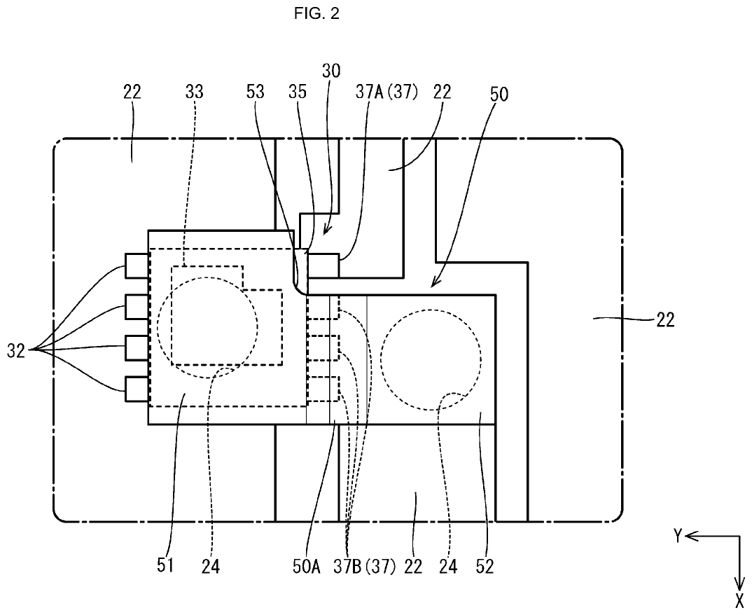

The first lead portion 32 is provided in a state of areal contact with the resin portion 35 on the lower surface of the semiconductor package 30, and a flat lead surface 32A is exposed from the resin portion 35. The second lead portion 33 is provided in a state of areal contact with the resin portion 35 on the upper surface of the semiconductor package 30, and a flat lead surface 33A is exposed from the resin portion 35. The end portion of the first lead portion 32 on the lateral side (the leftward side of FIG. 4) thereof includes four (a plurality of) terminals 32B that are arranged in a region outside of the resin portion 35 and the electrically conductive member 50. The terminals 32B can be connected to the electrically conductive paths 22 of the upper surface of the substrate 21 through soldering or the like. As shown in FIG. 2, the third lead portions 37 include one control terminal 37A and three (a plurality of) power terminals 37B that conduct a larger electrical current than the control terminal 37A, all of which are lined up in a row on one side of the resin portion 35. Note that the number of the control terminals 37A and the power terminals 37B on the other side of the resin portion 35 is not limited to that of the configuration described above, and for example only one side of the resin portion 35 may also be provided with one power terminal, or may be provided with a plurality of control terminals. The control terminal 37A is arranged at the end of the third lead portions 37 in the direction in which they are lined up. The power terminals 37B are electrically connected to the second lead portion 33 inside the resin portion 35. In the present embodiment, the plurality of power terminals 37B that are lined up on the control terminal 37A side of the resin portion 35 serve as FET source electrodes, the first lead portion 32 serves as an FET drain electrode, and the control terminal 37A serves an FET gate electrode. The lower surfaces of the plurality of third lead portions 37 are positioned in the same plane and are soldered to lands serving as the electrically conductive paths 22 formed on the surface layer of the substrate 21. The resin portion 35 is made from an insulating synthetic resin, and can be formed, for example, by injecting liquid resin into a metal mold with the chip 31 and the lead portions 32, 33, 37A, and 37B arranged therein and allowing the resin to harden (molding in a mold).

### Heat Dissipating Member 40

The heat dissipating member 40 is made from a highly thermally conductive metallic material such as aluminum, and an aluminum alloy and, as shown in FIG. 3, includes a flat upper surface and a plurality of heat dissipating fins 43 that are lined up in a comb-like shape on the lower surface of the heat dissipating member 40. In the region towards the middle of the upper surface of the heat dissipating member 40 in which the thermally conductive portion 29 is arranged, a platform 41 that has a constant thickness and protrudes upward is provided in a rectangular region. Also, boss portions 42 are formed protruding upwards at points around the circumferential edge of the upper surface of the heat dissipating member 40. The upper surfaces of the boss portions 42 are provided with screw holes 42A into which the screws 55 can be screwed and fastened.

Heat dissipating grease 45 is arranged between the head portions 27B of the rivets 27 and the upper surface of the heat dissipating member 40. The heat dissipating grease 45 is applied to the entire region of the platform 41 of the heat dissipating member 40, and may be a material such as silicone grease that has high thermal conductivity and is insulating. Heat that is transmitted from the electrically conductive member 50 to the rivet 27 on the right is transferred to the heat dissipating member 40 via the heat dissipating grease 45 and is dissipated to the outside from the heat dissipating member 40.

### Electrically Conductive Member 50

The electrically conductive member 50 is made of a metal that has high thermal conductivity and low electrical resistance such as copper, a copper alloy, aluminum, or an aluminum alloy, and, as shown in FIGS. 2 and 4, includes a first connection portion 51 that is connected to the semiconductor package 30, a second connection portion 52 that is connected to the thermally conductive portion 29, and a linking portion 50A that links the first connection portion 51 and the second connection portion 52 to each other. The first connection portion 51 has a rectangular plate-shape, and the second connection portion 52 has a rectangular plate-shape that is smaller than the first connection portion 51 in the front-rear direction. A cut-out portion 53 is cut out in a stepwise manner from the rear of the linking portion 50A and the second connection portion 52 between the first connection portion 51 and the second connection portion 52. When the electrically conductive member 50 is correctly positioned so that the electrically conductive member 50 is connected to the upper surface of the semiconductor package 30 and to the upper surface of the thermally conductive portion 29, the electrically conductive member 50 covers the top of the plurality of the power terminals 37B of the third lead portions 37 that are lined up to the side of the control terminal 37A while the top of the control terminal 37A of the third lead portions 37 is not covered by the electrically conductive member 50 and is exposed by the cut-out portion 53, thus ensuring insulation between the electrically conductive member 50 and the control terminal 37A. A solder-plated component may be used as the electrically conductive member 50, but there is no limitation thereto and a configuration is also possible in which an electrically conductive adhesive material is applied to the electrically conductive member, for example.

The following describes the application and effects of the present embodiment.

The circuit assembly 20 includes: a substrate 21 that is provided with the thermally conductive portion 29 that has thermal conductivity and passes through the substrate 21 in the plate-thickness direction thereof, and that includes the electrically conductive path 22; the semiconductor package 30 that is mounted to the substrate 21 and includes the chip 31, the resin portion 35 that covers the chip 31, the first lead portion 32 that is connected to the chip 31 and is exposed on the substrate 21 side of the resin portion 35, and the second lead portion 33 that is connected to the chip 31 and is exposed to the side opposite to the substrate 21 side of the resin portion 35; the heat dissipating member 40 that is arranged facing the side opposite to the semiconductor package 30 with respect to the substrate 21 and is connected to the thermally conductive portion 29 in such a way as to conduct heat; and the electrically conductive member 50 that connects the second lead portion 33 and the thermally conductive portion 29.

With the present embodiment, it is possible to dissipate the heat of the chip 31 in the semiconductor package 30 via the second lead portion 33, the electrically conductive member 50, and the thermally conductive portion 29 and from the heat dissipating member 40. Thus, heat that has been transmitted from the chip 31 to the second lead portion 33 can be dissipated from the heat dissipating member 40 without needing to provide a heat dissipating member on the second lead portion 33 side, and the heat of a semiconductor package 30 can be dissipated from a heat dissipating member 40, while suppressing an increase in the size of the device.

Also, the semiconductor package 30 further includes the plurality of third lead portions 37, the plurality of third lead portions 37 include the control terminal 37A and the power terminal 37B that conducts a larger electrical current than the control terminal 37A, and the electrically conductive member 50 covers the power terminal 37B and includes a cut-out portion 53 that is cut out in such a way as to not cover the control terminal 37A.

With such a configuration, the thermal conductive performance and heat dissipating performance is improved because the surface area of the plate surface of the electrically conductive member 50 is increased due to the electrically conductive member 50 covering the power terminals 37B, and it is also possible to ensure the insulation between the control terminal 37A and the electrically conductive member 50 due to the cut-out portion 53.

Also the circuit assembly includes a plurality of the semiconductor packages 30, wherein the electrically conductive member 50 connects the second lead portions 33 and the thermally conductive portions 29 of the plurality of semiconductor packages 30 to each other in parallel.

With such a configuration, it is possible to dissipate the heat of a plurality of semiconductor packages 30 because the electrically conductive members 50 are connected in parallel, and therefore it is possible to reduce production costs in comparison to a configuration in which the electrically conductive members 50 are provided individually on the semiconductor package 30.

The circuit assembly further includes the rivets 27 that includes the shafts 27A and the head portions 27B that have a larger diameter than the shafts 27A, wherein the substrate 21 includes the thermally conductive holes 24 that pass through the substrate 21 in the plate-thickness direction thereof, and the shafts 27A of the rivets 27 are inserted into the thermally conductive holes to constitute the thermally conductive portion 29, and the head portions 27B of the rivets 27 are connected to the heat dissipating member 40 in such a way as to conduct heat.

With such a configuration, it is possible to reduce production costs because ordinary inexpensive rivets 27 can be used as the thermally conductive portions 29.

### Second Embodiment

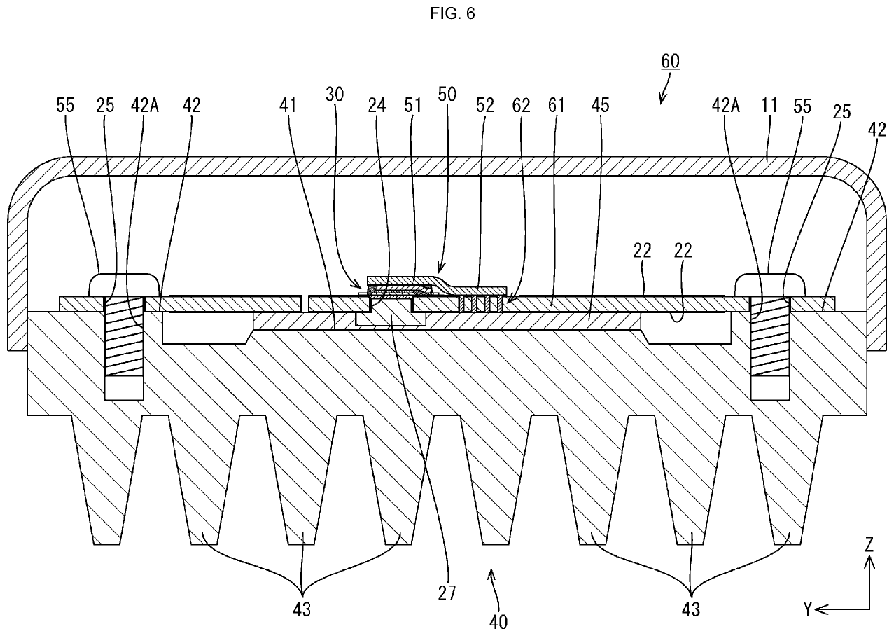

The following describes a second embodiment with reference to FIGS. 6 to 8.

In an electrical junction box 60 of the second embodiment, the second connection portion 52 of the electrically conductive member 50 is connected to the top of thermal vias 62 in a substrate 61. Configurations in the following description that are the same as those of the first embodiment will use the same reference numerals and descriptions thereof will be omitted.

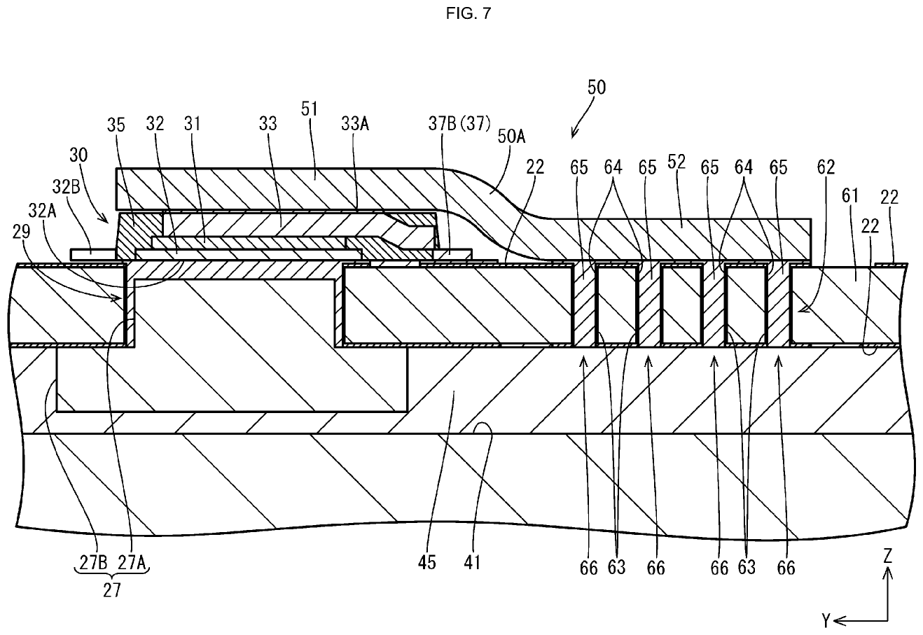

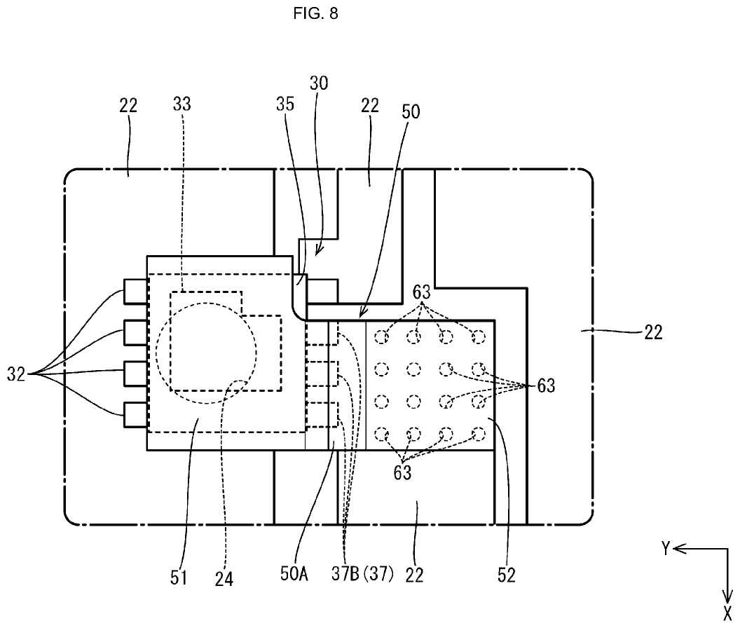

As shown in FIGS. 7 and 8, the thermal vias 62 are provided as a plurality of thermally conductive holes 63 that pass through the substrate 21 and are lined up lengthwise and breadth-wise, and the walls of the thermally conductive holes 63 are in areal contact with electrically conductive walls 64 that are made from a metal such as copper foil. The thermally conductive holes 63 (the electrically conductive walls 64) are filled with solder 65. The upper end of the solder 65 is connected to the second connection portion 52 of the electrically conductive member 50, and the lower end of the solder 65 is in areal contact with the heat dissipating grease 45 on the heat dissipating member 40. The electrically conductive walls 64 and the solder 65 form a thermally conductive portion 66 that increases the thermal conductivity between the electrically conductive member 50 and the heat dissipating member 40.

With the second embodiment, the thermal vias 62 of the substrate 61 make it possible to improve the dissipation of the heat of the semiconductor package 30.

### Third Embodiment

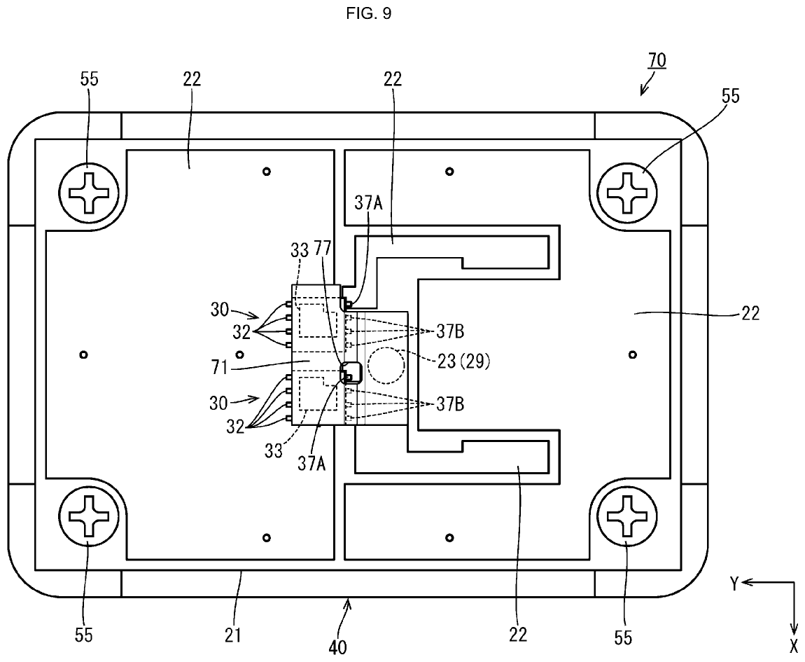

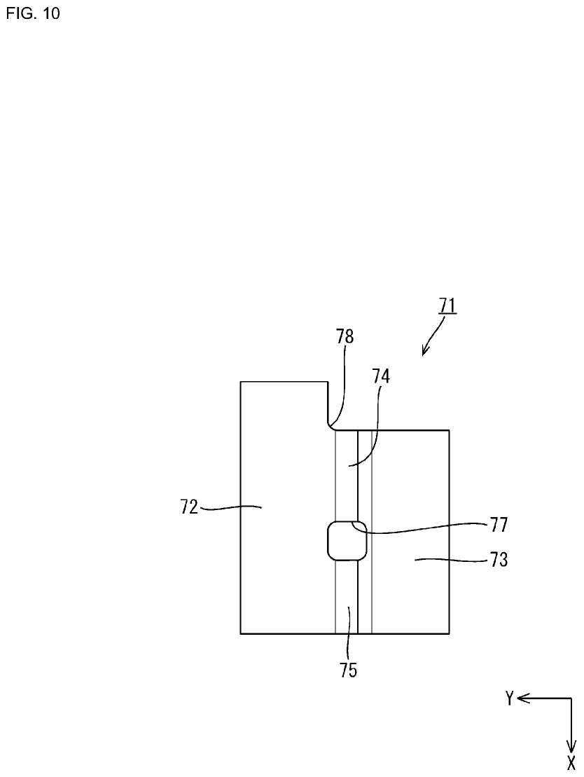

The following describes a third embodiment with reference to FIGS. 9 and 10.

As shown in FIG. 9, in the circuit assembly 70 of the third embodiment, a plurality of the semiconductor packages 30 and the thermally conductive portion 29 are connected to each other in parallel by an electrically conductive member 71. Configurations in the following description that are the same as those of the first embodiment will use the same reference numerals and descriptions thereof will be omitted.

Two (a plurality of) semiconductor packages 30 are mounted on the substrate 21 in a line in the front-rear direction. As shown in FIG. 10, the electrically conductive member 71 includes a first connection portion 72 that is connected to two (a plurality of) semiconductor packages 30, a second connection portion 73 that is connected to one thermally conductive portion 29, and a first electrically conductive portion 74 and a second electrically conductive portion 75 that connect the second lead portions 33 and the thermally conductive portions 29 of the plurality of semiconductor packages 30 to each other in parallel. The first electrically conductive portion 74 and the second electrically conductive portion 75 extend in the left-right direction with substantially the same width, and cut-out portions 77 and 78 are formed cut out of and passing through the first electrically conductive portion 74 and the second electrically conductive portion 75 in such a way that exposes the control terminal 37A. The cut-out portion 77 is a rectangular through-hole, and the cut-out portion 78 is cut out of the outer peripheral edge of the electrically conductive member 71 in a stepwise shape. When the electrically conductive member 71 is correctly positioned and connected to the plurality of semiconductor packages 30 and the thermally conductive portion 29, the electrically conductive member 50 covers the top of the plurality of power terminals 37B and the electrically conductive member 50 does not cover the control terminals 37A due to the cut-out portions 77 and 78, and therefore it is possible to ensure insulation between the electrically conductive member 50 and the control terminal 37A.

### Other Embodiments

The technology disclosed in this description is not limited to the embodiment described with the above description and drawings, and the following embodiments are also included in the technical scope of the technique disclosed in this specification.

The substrates 21 and 61 are constituted by insulating substrates, but there is no limitation thereto and configurations are also possible in which bus bars made from a metal material such as copper are laid on the insulating substrate. Also, the substrate 21 is not limited to being a single-layer substrate, and configurations are also possible in which the substrate 21 is a multi-layered substrate on which multiple conductive paths are formed on an insulating board.

The configuration described above includes thermally conductive portions 29 and 66 in which the thermally conductive holes 24 and 63 in the substrates 21 and 61 are filled with the solder 28 and 65, but there is no limitation thereto, and configurations are also possible in which, for example, the thermally conductive holes 24 and 63 are not filled with the solder 28 and 65, only the electrically conductive walls 23 and 64 act as thermally conductive portions, and heat is transmitted from the electrically conductive members 50 and 71 to the heat dissipating member 40.

The number of semiconductor packages 30 is not limited to the number in the foregoing description, and can be changed as appropriate. For example, configurations are also possible in which the heat of three of more semiconductor packages 30 is transmitted to the thermally conductive portion by electrically conductive members configured in parallel.

The thermally conductive holes 24, the shafts 27A, and the electrically conductive walls 23 and 64 have circular shapes, but there is no limitation thereto, and configurations are also possible in which these components have oval shapes or polygonal shapes.

The electrically conductive members 50 and 71 are configured to include the cut-out portions 53, 77, and 78, but a configuration is also possible in which the electrically conductive member does not include any cut-out portions. For example, configurations are possible in which the electrically conductive member has a rectangular shape that does not include a cut-out portion.

The electrically conductive members 50 and 71 cover the plurality of power terminals 37B that are lined up on the resin portion 35 on the control terminal 37A side thereof, but there is no limit thereto and configurations are also possible in which the electrically conductive member does not cover the power terminals 37B (and the control terminal 37A) and exposes the power terminals 37B (and control terminal 37A). For example, a configuration is possible in which the electrically conductive member extends to the side that does not include power terminals 37B (nor control terminal 37A) with respect to the semiconductor package (for example, rotating the conductive member ninety degrees on a horizontal plane), and the conductive member does not cover the power terminals 37B and the control terminal 37A.

1. A circuit assembly comprising:
a substrate that is provided with a thermally conductive portion that has thermal conductivity and passes through the substrate in the plate-thickness direction thereof, and that includes an electrically conductive path;
a semiconductor package that is mounted to the substrate and includes a chip, a resin portion that covers the chip, a first lead portion that is connected to the chip and is exposed on the substrate side of the resin portion, and a second lead portion that is connected to the chip and is exposed to the side opposite to the substrate side of the resin portion;
a heat dissipating member that is arranged facing the side opposite to the semiconductor package with respect to the substrate and is connected to the thermally conductive portion in such a way as to conduct heat; and
an electrically conductive member that connects the second lead portion and the thermally conductive portion.

2. The circuit assembly according to claim 1, wherein the semiconductor package further includes a plurality of third lead portions, the plurality of third lead portions include a control terminal and a power terminal that conducts a larger electrical current than the control terminal, and
the electrically conductive member covers the power terminal and includes a cut-out portion that is cut out in such a way as to not cover the control terminal.

3. The circuit assembly according to claim 1, further including:
a plurality of the semiconductor packages, wherein
the electrically conductive member connects the second lead portions and the thermally conductive portions of the plurality of semiconductor packages to each other in parallel.

4. The circuit assembly according to claim 1, further comprising:
a rivet that includes a shaft and a head portion that has a larger diameter than the shaft, wherein
the substrate includes a thermally conductive hole that passes through the substrate in the plate-thickness direction thereof, and
the shaft of the rivet is inserted into the thermally conductive hole to constitute the thermally conductive portion, and the head portion of the rivet is connected to the heat dissipating member in such a way as to conduct heat.

5. An electrical junction box comprising:
the circuit assembly according to claim 1, and
a case that accommodates the circuit assembly.

6. The circuit assembly according to claim 2, comprising
a plurality of the semiconductor packages, wherein
the electrically conductive member connects the second lead portions and the thermally conductive portions of the plurality of semiconductor packages to each other in parallel.

7. The circuit assembly according to claim 2, further comprising:
a rivet that includes a shaft and a head portion that has a larger diameter than the shaft, wherein
the substrate includes a thermally conductive hole that passes through the substrate in the plate-thickness direction thereof, and
the shaft of the rivet is inserted into the thermally conductive hole to constitute the thermally conductive portion, and the head portion of the rivet is connected to the heat dissipating member in such a way as to conduct heat.

8. The circuit assembly according to claim 3, further comprising:
a rivet that includes a shaft and a head portion that has a larger diameter than the shaft, wherein
the substrate includes a thermally conductive hole that passes through the substrate in the plate-thickness direction thereof, and
the shaft of the rivet is inserted into the thermally conductive hole to constitute the thermally conductive portion, and the head portion of the rivet is connected to the heat dissipating member in such a way as to conduct heat.

9. The circuit assembly according to claim 8, wherein the semiconductor package further comprises a plurality of third lead portions,
the plurality of third lead portions include a control terminal and a power terminal that conducts a larger electrical current than the control terminal, and
the electrically conductive member covers the power terminal and includes a cut-out portion that is cut out in such a way as to not cover the control terminal.

10. The electrical junction box according to claim 5, wherein the semiconductor package further includes a plurality of third lead portions, the plurality of third lead portions include a control terminal and a power terminal that conducts a larger electrical current than the control terminal and the electrically conductive member covers the power terminal and includes a cut-out portion that is cut out in such a way as to not cover the control terminal; and
a case that accommodates the circuit assembly.

11. The electrical junction box according to claim 10, further including:
a plurality of the semiconductor packages, wherein
the electrically conductive member connects the second lead portions and the thermally conductive portions of the plurality of semiconductor packages to each other in parallel.

12. The electrical junction box according to claim 11 further comprising:
a rivet that includes a shaft and a head portion that has a larger diameter than the shaft, wherein
the substrate includes a thermally conductive hole that passes through the substrate in the plate-thickness direction thereof, and
the shaft of the rivet is inserted into the thermally conductive hole to constitute the thermally conductive portion, and the head portion of the rivet is connected to the heat dissipating member in such a way as to conduct heat.
